(19) United States
(12) Patent Application Publication
(10) Pub. No.: US 2020/0274017 A1
(43) Pub. Date: Aug. 27, 2020

(54) OPTOELECTRONIC DEVICE WITH INCREASED OPEN-CIRCUIT VOLTAGE

(71) Applicant: Artilux, Inc., Menlo Park, CA (US)

(72) Inventors: Yun-Chung Na, HSINCHU COUNTY (TW); Yen-Cheng Lu, HSINCHU COUNTY (TW); Yu-Hsuan Liu, HSINCHU COUNTY (TW); Chung-Chih Lin, HSINCHU COUNTY (TW); Tsung-Ting Wu, HSINCHU COUNTY (TW); Szu-Lin Cheng, HSINCHU COUNTY (TW)

(21) Appl. No.: 16/796,960

(22) Filed: Feb. 21, 2020

Related U.S. Application Data
(60) Provisional application No. 62/809,712, filed on Feb. 24, 2019.
(60) Provisional application No. 62/844,746, filed on May 8, 2019.

(51) Int. Cl. H01L 31/0745; H01L 31/048; H01L 31/0312

(52) U.S. Cl. CPC H01L 31/0745; H01L 31/03125; H01L 31/048

(57) ABSTRACT

An optoelectronic device includes a first semiconductor region of a first conductivity type, a second semiconductor region of a second conductivity type different from the first conductivity type, and a photoelectric conversion region between the first semiconductor region and the second semiconductor region. The photoelectric conversion region is of a third conductivity type the same as the first conductivity type.

### CROSS REFERENCE TO RELATED APPLICATIONS

This application claims priority from U.S. provisional application No. 62/809,712, filed Feb. 24, 2019 and priority from U.S. provisional application No. 62/844,746, filed May 8, 2019, which are incorporated by reference herein in their entireties.

### BACKGROUND OF THE INVENTION

### 1. Field of the Invention

The present invention relates generally to an optoelectronic device, and more particularly to a photovoltaic cell for converting optical signal into electricity.

### 2. Description of the Prior Art

A photovoltaic (PV) cell, which is a device for converting radiation to electrical energy, may comprise P-type and N-type diffusion regions. Radiation impinging on the photovoltaic cell creates electrons and holes that migrate to the diffusion regions, thereby creating voltage differentials between the diffusion regions. The diffusion regions are electrically connected to corresponding terminals to allow an external electrical circuit to be connected to and be powered by the photovoltaic cell. A passive photovoltaic cell is designed to convert radiation all the way from UV to visible to IR ranges from sun, imposes specific requirements on designing solar cells.

An active photovoltaic cell is designed to charge an electronic device/storage with light-emitting diodes (LEDs) or laser power. In an active photovoltaic cell, the demand of converting single-wavelength or narrow-band radiation spectrum from LEDs or laser may impose different requirements on designing cells, such as light from led/laser should be invisible and eye-safe or the photovoltaic cell should be power-efficient, i.e., large open-circuit voltage (V_{OC}) and large short-circuit current (I_{SC}).

### SUMMARY OF THE INVENTION

It is one object of the present application to provide an improved optoelectronic device with increased open-circuit voltage.

One aspect of the present application provides an optoelectronic device including an optoelectronic unit including a photoelectric conversion layer for converting an optical signal into an electrical signal; and a first semiconductor layer and a second semiconductor layer sandwiching the photoelectric conversion layer. The first semiconductor layer and the second semiconductor layer have different atomic arrangements.

According to one embodiment, an optoelectronic device includes an optoelectronic unit including a photoelectric conversion layer for converting an optical signal into an electrical signal; and a first semiconductor layer and a second semiconductor layer sandwiching the photoelectric conversion layer. The photoelectric conversion layer includes a material including a Group IV element, the first semiconductor layer includes a material including a Group IV element, and the Group IV element of the first semiconductor layer is different from the Group IV element of the photoelectric conversion layer.

According to one embodiment, an optoelectronic device includes an optoelectronic unit including a photoelectric conversion layer for converting an optical signal into an electrical signal. The photoelectric conversion layer includes germanium.

Another aspect of the present application provides an optoelectronic device including a first semiconductor region of a first conductivity type; a second semiconductor region of a second conductivity type different from the first conductivity type; and a photoelectric conversion region between the first semiconductor region and the second semiconductor region. The photoelectric conversion region is of a third conductivity type the same as the first conductivity type.

According to one embodiment, an optoelectronic device includes a photoelectric conversion region including a first side and a second side opposite to the first side; a first semiconductor region of a first conductivity type; and a second semiconductor region of a second conductivity type different from the first conductivity type. The first semiconductor region and the second semiconductor region are both over the first side of photoelectric conversion region, and wherein the photoelectric conversion region is of a third conductivity type the same as the first conductivity type.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic, cross-sectional diagram showing an exemplary optoelectronic device in accordance with one embodiment of the present application;

FIG. 2 is an enlarged view of an optoelectronic unit with asymmetric double intrinsic heterojunction configuration in accordance with one embodiment of the present application;

FIG. 3 is a band diagram showing the band structure of the optoelectronic unit in FIG. 2;

FIG. 4 is a schematic, cross-sectional diagram showing an exemplary optoelectronic device in accordance with another embodiment of the present application;

FIG. 5A is a schematic, cross-sectional diagram showing an exemplary optoelectronic device in accordance with still another embodiment of the present application;

FIG. 5B is a schematic, cross-sectional diagram showing an exemplary optoelectronic device in accordance with still another embodiment of the present application.

FIG. 6 is a band diagram showing the band structure of the exemplary optoelectronic device of FIG. 5A;

FIG. 7 is a schematic, cross-sectional diagram showing an exemplary optoelectronic device in accordance with still another embodiment of the present application;

FIG. 8 is a schematic, cross-sectional diagram showing an exemplary optoelectronic device in accordance with still another embodiment of the present application;

FIG. 9 is a schematic, cross-sectional diagram showing an exemplary optoelectronic device in accordance with still another embodiment of the present application;

FIG. 10 is a schematic, cross-sectional diagram showing an exemplary optoelectronic device in accordance with still another embodiment of the present application;

FIG. 11 is a schematic, cross-sectional diagram showing an exemplary optoelectronic device in accordance with still another embodiment of the present application;

FIG. 12 is a schematic, cross-sectional diagram showing an exemplary optoelectronic device in accordance with still another embodiment of the present application;

FIG. 13 is a schematic, cross-sectional diagram showing an exemplary optoelectronic device in accordance with still another embodiment of the present application;

FIG. 14A is a schematic, top-view diagram showing an exemplary optoelectronic device in accordance with still another embodiment of the present application;

FIG. 14B is a schematic, cross-sectional diagram along an A-A′ line in FIG. 14A;

FIG. 15 is a schematic, cross-sectional diagram showing an exemplary optoelectronic device in accordance with still another embodiment of the present application;

FIG. 16 is a schematic, cross-sectional diagram showing an exemplary optoelectronic device in accordance with still another embodiment of the present application;

FIG. 17 is a schematic, cross-sectional diagram showing an exemplary optoelectronic device in accordance with still another embodiment of the present application;

FIG. 18 is a schematic, cross-sectional diagram showing an exemplary optoelectronic device in accordance with still another embodiment of the present application;

FIG. 19 demonstrates simulation results of I-V curves of optoelectronic devices in FIG. 11 with different peak concentrations; and

FIG. 20 shows the I-V curves of different optoelectronic devices.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized and structural, logical, and electrical changes may be made without departing from the scope of the present invention. Therefore, the following detailed description is not to be considered as limiting, but the embodiments included herein are defined by the scope of the accompanying claims.

In the present application, the term “germanium-silicon (GeSi)” refers to a GeₓSi₁₋ₓ, wherein 0<x<1. The term “intrinsic” refers to a semiconductor material without intentionally adding dopants.

As used herein, the terms such as “first”, “second” and “third” describe various elements, components, regions, layers and/or sections, these elements, components, regions, layers and/or sections should not be limited by these terms. These terms may be only used to distinguish one element, component, region, layer or section from another. The terms such as “first”, “second”, and “third” when used herein do not imply a sequence or order unless clearly indicated by the context.

Germanium (Ge) has high carrier mobility (e.g., high hole and electron mobility) and optical absorption as compared to silicon (Si). This is one reason why Ge is useful for devices that require enhanced performance and/or high quantum efficiency. Ge grown on Si substrate may be a suitable platform for active photovoltaic cells, e.g., it can absorb NIR wavelengths >1.4 um that are invisible and eye-safe, with large quantum efficiency boosting I_{SC}. However, when being processed as a photodiode, its relatively large dark current at a reverse-bias suggests the presence of defects as recombination centers at a forward-bias, which may reduce V_{OC} and the power efficiency.

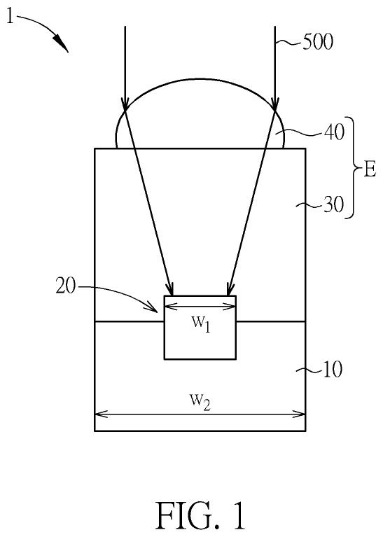

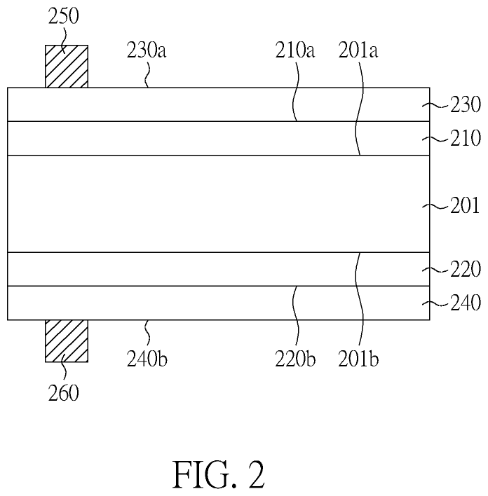

Please refer to FIG. 1 and FIG. 2. FIG. 1 is a schematic, cross-sectional diagram showing an exemplary optoelectronic device 1 in accordance with one embodiment of the present application. FIG. 2 is an enlarged view of an optoelectronic unit with asymmetric double intrinsic heterojunction configuration in accordance with one embodiment of the present application. As shown in FIG. 1, the optoelectronic device 1 includes a substrate 10, an optoelectronic unit 20 supported by the substrate 10, and an optical element E disposed on the optoelectronic unit 20. According to one embodiment of the present application, for example, the substrate 10 may include silicon. According to one embodiment of the present application, for example, the optical element E may include a spacer layer 30 disposed on the optoelectronic unit 20 and the silicon substrate 10, and a lens 40 disposed on the spacer layer 30.

According to one embodiment of the present application, the lens 40 is disposed to focus incident light 500 toward the optoelectronic unit 20. According to one embodiment of the present application, the spacer layer 30 may include optical transmissive material, which is transparent to the target wavelength of the incident light 500. The optical transmissive material includes, but is not limited to, polymer, dielectric material, transparent material, partially transparent material, or the like. The material may include, and is not limited to, Si, SiO₂, Si₃N₄, or any combination thereof. According to one embodiment of the present application, the spacer layer 30 may include a dielectric material layer that is transparent to the incident light 500 such as near IR (e.g., wavelength >750 nm), such that the incident light 500 can be absorbed by the optoelectronic unit 20. Although not shown in the figures, it is to be understood that the optoelectronic device 1 may include multiple optoelectronic units 20, and the multiple optoelectronic units 20 may be arranged in a two-dimensional array.

According to one embodiment of the present application, a material of the spacer layer 30 is different from a material of the lens 40. According to one embodiment of the present application, a thickness of the spacer layer 30 is greater than a thickness of the lens 40. The spacer layer 30 is to enhance the amount of the incident light 500 entering the optoelectronic unit 20. According to one embodiment of the present application, the spacer layer has a thickness not less than 5 μm. According to one embodiment of the present application, the thickness of the spacer layer 30 is not more than 100 μm. According to one embodiment of the present application, a width w₁ of the optoelectronic unit 20 is less than a width w₂ of the substrate 10.

According to one embodiment of the present application, the optoelectronic unit 20 may be partially embedded in the substrate 10. According to another embodiment of the present application, the optoelectronic unit 20 may be fully embedded in the substrate 10. According to still another embodiment of the present application, the optoelectronic unit 20 may not be embedded in the substrate 10 and may be entirely on the substrate 10.

As shown in FIG. 2, the optoelectronic unit 20 includes an asymmetric double intrinsic heterojunction configuration. According to one embodiment of the present application, for example, the optoelectronic unit 20 includes a photoelectric conversion layer 201 for converting an optical signal into an electrical signal, a first semiconductor layer 210 disposed on a first side 201a of the photoelectric conversion layer 201, and a second semiconductor layer 220 disposed on a second side 201b of the photoelectric conversion layer 201. The photoelectric conversion layer 201 is sandwiched between the first semiconductor layer 210 and the second semiconductor layer 220. The first semiconductor layer 210 has a band gap greater than a band gap of the photoelectric conversion layer 201. According to one embodiment of the present application, the second semiconductor layer 220 also has a band gap greater than the band gap of the photoelectric conversion layer 201. The first semiconductor layer 210 and the second semiconductor layer 220 each with a band gap greater than the band gap of the photoelectric conversion layer 201 are for increasing the open-circuit voltage of the optoelectronic unit 20. According to one embodiment of the present application, the material of the substrate 10 is different from the material of the photoelectric conversion layer 201.

According to one embodiment of the present application, the photoelectric conversion layer 201 has a thickness not less than 500 nm, not more than 10 μm, for higher efficiency. According to one embodiment of the present application, the first semiconductor layer 210 has a thickness not less than 10 nm, not more than 1 μm, for better surface passivation of the photoelectric conversion layer 201. According to one embodiment of the present application, the second semiconductor layer 220 has a thickness not less than 10 nm, not more than 10 μm, for better growth quality of the photoelectric conversion layer 201. According to one embodiment of the present application, the first semiconductor layer 210 has an atomic arrangement that is different from that of the second semiconductor layer 220. For example, the first semiconductor layer 210 is amorphous, and the second semiconductor layer 220 is crystalline. The term “crystalline” includes single crystalline or polycrystalline. According to one embodiment of the present application, the atomic arrangement can be determined by any suitable method, such as an X-ray diffraction analysis (XRD). According to one embodiment of the invention, the first semiconductor layer 210 and the second semiconductor layer 220 are both intrinsic. According to one embodiment of the present application, the first semiconductor layer 210 is in direct contact with the photoelectric conversion layer 201. According to one embodiment of the present application, the second semiconductor layer 220 is in direct contact with the photoelectric conversion layer 201.

According to one embodiment of the present application, a material of the photoelectric conversion layer 201 is different from a material of the first semiconductor layer 210. According to one embodiment of the present application, a material of the photoelectric conversion layer 201 is different from both a material of the first semiconductor layer 210 and a material of the second semiconductor layer 220. According to one embodiment of the present application, the photoelectric conversion layer 201 may include a material including a Group IV element, and the first semiconductor layer 210 may include a material including a Group IV element. According to one embodiment of the present application, the Group IV element of the first semiconductor layer 210 is different from the Group IV element of the photoelectric conversion layer 201. According to one embodiment of the present application, for example, the photoelectric conversion layer 201 is configured to absorb photons having a peak wavelength in an invisible wavelength range not less than 800 nm, such as 850 nm, 940 nm, 1050 nm, 1064 nm, 1310 nm, 1350 nm, or 1550 nm. In some embodiments, the invisible wavelength range is not more than 2000 nm. According to one embodiment of the present application, the photoelectric conversion layer 201 may include Ge or GeSi. According to one embodiment of the present application, the photoelectric conversion layer 201 is composed of Ge or GeSi. According to one embodiment of the present application, for example, the material of the first semiconductor layer 210 and the material of the second semiconductor layer 220 include Si.

According to one embodiment of the present application, for example, the photoelectric conversion layer 201 may be a crystalline layer, the first semiconductor layer 210 may be an amorphous layer, and the second semiconductor layer 220 may be a crystalline layer. The material of the photoelectric conversion layer 201 is different from both a material of the first semiconductor layer 210 and a material of the second semiconductor layer 220. A first heterojunction is formed between the photoelectric conversion layer 201 and the first semiconductor layer 210, and a second heterojunction is formed between the photoelectric conversion layer 201 and the second semiconductor layer 220. Since the first semiconductor layer 210 has an atomic arrangement different from that of the second semiconductor layer 220, the optoelectronic unit 20 includes an asymmetric double heterojunction configuration.

According to one embodiment of the present application, for example, the photoelectric conversion layer 201 may be an intrinsic crystalline Ge layer, the first semiconductor layer 210 may be an intrinsic amorphous Si layer, and the second semiconductor layer 220 may be an intrinsic crystalline Si layer. A first heterojunction is formed between the photoelectric conversion layer 201 and the first semiconductor layer 210, and a second heterojunction is formed between the photoelectric conversion layer 201 and the second semiconductor layer 220. Since the first semiconductor layer 210 has an atomic arrangement different from that of the second semiconductor layer 220, the optoelectronic unit 20 includes an asymmetric double intrinsic heterojunction configuration.

It is to be understood that in some embodiments, the amorphous Si layer may be transformed into polycrystalline Si layer or microcrystalline Si layer after a thermal process or other process treatments. According to one embodiment of the invention, the first semiconductor layer 210 and the second semiconductor layer 220 may have different conductivity types, for example, the first semiconductor layer 210 may be lightly P doped, such as not more than 1×10¹⁷ cm⁻³, and the second semiconductor layer 220 may be lightly N-doped, such as not more than 1×10¹⁷ cm⁻³. Further, in some embodiments, the intrinsic crystalline Ge layer may be P type without doping. In some embodiments, the photoelectric conversion layer 201 may be lightly P doped or N doped, such as not more than 1×10¹⁷ cm⁻³.

According to one embodiment of the present application, the optoelectronic device 1 may further include a first contact layer 230 disposed on an upper surface 210a of the first semiconductor layer 210. According to one embodiment of the present application, the optoelectronic device 1 may further include a second contact layer 240 disposed on a lower surface 220b of the second semiconductor layer 220. According to one embodiment of the present application, a conductivity type of the second contact layer 240 is different from a conductivity type of the first contact layer 230. For example, the first contact layer 230 may be a P-type layer, and the second contact layer 240 may be an N-type layer. According to one embodiment of the present application, the first contact layer 230 and the second contact layer 240 include semiconductor material. According to one embodiment of the present application, the first contact layer 230 has a band gap greater than a band gap of the photoelectric conversion layer 201. According to one embodiment of the present application, the second contact layer 240 also has a band gap greater than the band gap of the photoelectric conversion layer 201. According to one embodiment of the present application, the first contact layer 230 has an atomic arrangement that is different from that of the second contact layer 240. For example, the first contact layer 230 may be an amorphous layer, and the second contact layer 240 may be a crystalline layer. According to one embodiment of the present application, the atomic arrangement of the first contact layer 230 is the same as the first semiconductor layer 210. The atomic arrangement of the second contact layer 240 is the same as the second semiconductor layer 220. For example, the first contact layer 230 may be an amorphous layer, and the first semiconductor layer 210 may also be an amorphous layer. For another example, the second contact layer 240 may be a crystalline layer, and the second semiconductor layer 220 may also be a crystalline layer.

According to one embodiment of the present application, an optical signal may enter the photoelectric conversion layer 201 from the first contact layer 230, from the second contact layer 240 or from a side wall of the photoelectric conversion layer 201 at an angle equal or greater than 0 degree, wherein the side wall is between the first side 201a and the second side 201b.

According to one embodiment of the present application, the optoelectronic device 1 may further include a conductive contact element 250 disposed on an upper surface 230a of the first contact layer 230 and a conductive contact element 260 disposed on a lower surface 240b of the second contact layer 240. The conductive contact element 250 includes conductive material, such as metal or transparent conducting oxides or transparent conducting films.

According to one embodiment of the present application, the first contact layer 230 has a peak concentration not less than 1×10¹⁸ cm⁻³, and not more than 1×10²¹ cm⁻³ for ohmically contacting with the conductive contact element 250. According to one embodiment of the present application, the second contact layer 240 has a peak concentration not less than 1×10¹⁸ cm⁻³, and not more than 1×10²¹ cm⁻³ for ohmically contacting with the conductive contact element 260. According to one embodiment of the present application, the second contact layer 240 may be formed in the substrate 10. According to one embodiment of the present application, the first contact layer 230 has a thickness not less than 10 nm, and not more than 4 μm for better back end integrability. According to one embodiment of the present application, the second contact layer 240 has a thickness not less than 10 nm, and not more than 4 μm for better back end integrability.

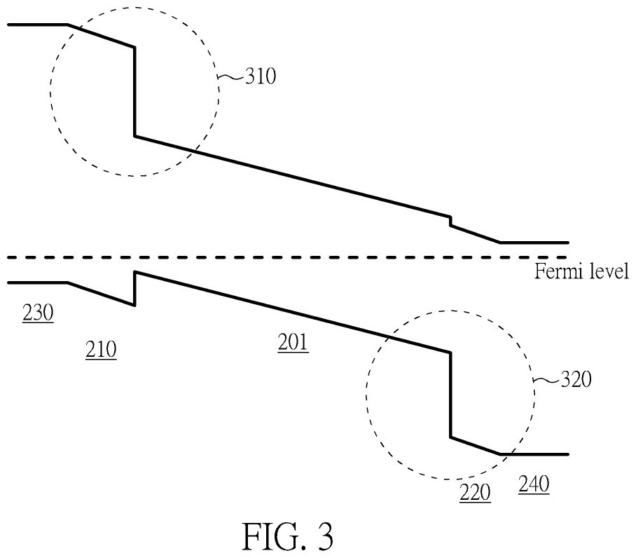

Please refer to FIG. 3. FIG. 3 is a band diagram showing the band structure of the optoelectronic unit 20 in FIG. 2. In FIG. 3, since the asymmetric double heterojunctions are formed in the optoelectronic unit 20, a first barrier 310 and a second barrier 320 may be formed. The first barrier 310 prevents the electrons from moving toward the first semiconductor layer 210. Similarly, the second barrier 320 prevents the holes from moving toward the second semiconductor layer 220. As a result, the chance for the electrons to be recombined in the first semiconducting layer 210, the first contact layer 230, and the conducting contact element 250 is reduced; and the chance for the holes to be recombined in the second semiconducting layer 220, the second contact layer 240, and the conducting contact element 260 is also reduced. Accordingly, the V_{OC} is improved.

According to one embodiment of the present application, because the spacer layer 30 and the lens 40 are disposed to focus a larger optical area into a smaller optical area so that only a small optoelectronic unit 20 is needed, and therefore the photoelectric conversion layer 201 in the optoelectronic unit 20 may be down-scaled. Since the width w₁ of the optoelectronic unit 20 is less than the width w₂ of the substrate 10, the diode diffusion current at a forward-bias can be reduced, which in turn increases V_{OC}. According to one embodiment of the present application, the optoelectronic device 1 is suitable for active photovoltaic cells, and there is nearly no absorption (or very little absorption) in the first semiconductor layer 210 and the second semiconductor layer 220.

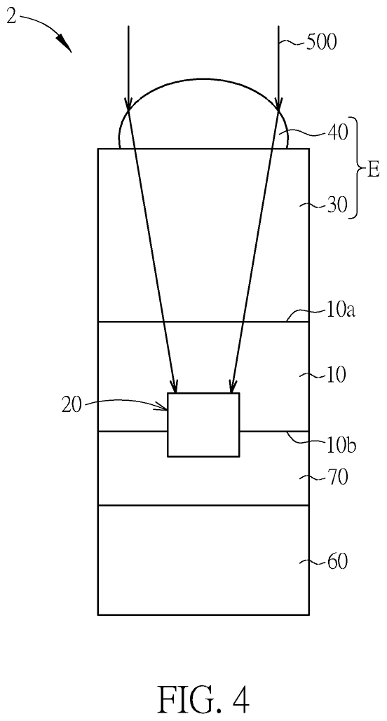

FIG. 4 is a schematic, cross-sectional diagram showing an exemplary optoelectronic device 2 in accordance with another embodiment of the present application, wherein similar layers, regions or elements are designated by the same numeral numbers. As shown in FIG. 4, the optoelectronic device 2 includes a substrate 10, an optoelectronic unit 20 supported by the substrate 10, and an optical element E disposed on an upper surface 10a of the substrate 10. According to one embodiment of the present application, for example, the substrate 10 may include silicon. According to one embodiment of the present application, for example, the optical element E may include a spacer layer 30 disposed on the optoelectronic unit 20 and the silicon substrate 10, and a lens 40 disposed on the spacer layer 30.

According to one embodiment of the present application, the spacer layer 30 is not in direct contact with the optoelectronic unit 20. According to one embodiment of the present application, the optoelectronic device 2 further includes a carrier 60 bonded to a lower surface 10b of the substrate 10. A bonding layer 70 may be disposed between the lower surface 10b of the substrate 10 and the carrier 60. According to one embodiment of the present application, the carrier 60 and the optoelectronic unit 20 are connected together by the bonding layer 70. According to one embodiment of the present application, the carrier 60 may include a silicon substrate, but is not limited thereto. According to one embodiment of the present application, the bonding layer 70 may include dielectric material, oxide material, and/or metal material, such as Au and/or In.

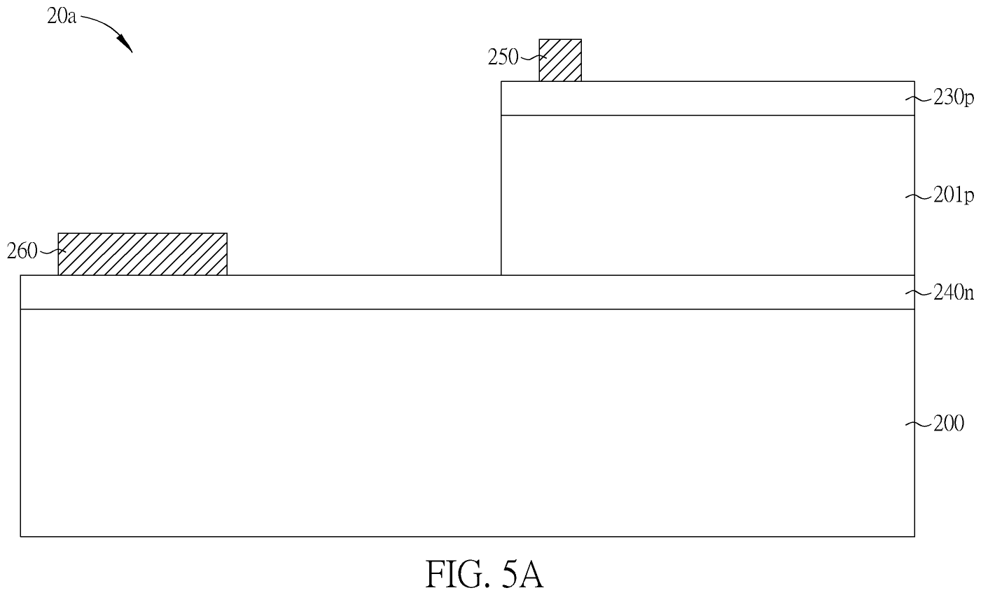

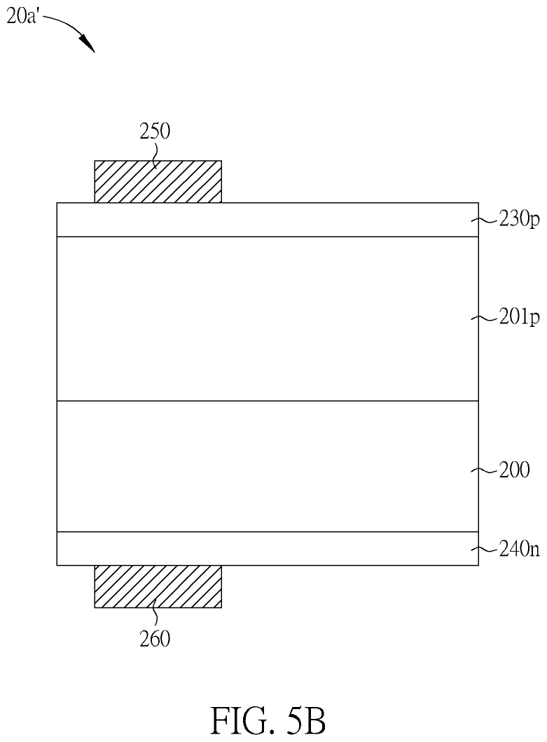

FIG. 5A is a schematic, cross-sectional diagram showing an exemplary optoelectronic device 20a in accordance with still another embodiment of the present application. For example, the optoelectronic device 20a may be a photovoltaic cell. As shown in FIG. 5A, the optoelectronic device 20a includes a substrate 200, a first semiconductor region 230p of a first conductivity type; a second semiconductor region 240n of a second conductivity type different from the first conductivity type; and a photoelectric conversion region 201p between the first semiconductor region 230p and the second semiconductor region 240n. In other words, the first semiconductor region 230p and the second semiconductor region 240n with different conductivity types are at two opposite sides of the photoelectric conversion region 201p. The second semiconductor region 240n can be formed in the substrate 200. The photoelectric conversion region 201p is supported by the substrate 200. According to one embodiment of the present application, the material of the substrate 200 is different from the material of the photoelectric conversion region 201p. The photoelectric conversion region 201p is of a third conductivity type the same as the first conductivity type. In some embodiments, the first conductivity type is P type, and the second conductivity type is N type. In some embodiments, a conductive contact element 250 such as an electrode may be disposed on the first semiconductor region 230p and a conductive contact element 260 such as a electrode may be disposed on the second semiconductor region 240n. The conductive contact elements 250, 260 include conductive material such as metal or transparent conducting oxides or transparent conducting films. In some embodiments, the conductive contact elements 250, 260 can be on the same side of the substrate 200.

According to some embodiments, the first semiconductor region 230p includes a first dopant having a first peak concentration not less than 1×10¹⁸ cm⁻³. The second semiconductor region 240n includes a second dopant having a second peak concentration not less than 1×10¹⁸ cm⁻³. The photoelectric conversion region 201p includes a third dopant having a third peak concentration. In some embodiments, the third peak concentration is not less than 1×10¹⁷ cm⁻³. According to some embodiments, the third peak concentration is between 1×10¹⁷ cm⁻³ and 1×10¹⁹ cm⁻³.

According to some embodiments, the first peak concentration is higher than the third peak concentration. According to some embodiments, the first dopant and the third dopant can be a P-type dopant including a group-III element. The first dopant and the third dopant can be the same of can be different. In some embodiments, the P-type dopant is boron. The second dopant includes an N-type dopant. The N-type dopant can be a group-V element. In some embodiments, the N-type dopant is phosphorous. According to some embodiments, a material of the first semiconductor region 230p is different from a material of the photoelectric conversion region 201p. In some embodiment, a material of the second semiconductor region 240n is different from the material of the photoelectric conversion region 201p.

According to some embodiments, a band gap of the first semiconductor region 230p is greater than a band gap of the photoelectric conversion region 201p. According to some embodiments, a band gap of the second semiconductor region 240n is greater than a band gap of the photoelectric conversion region 201p.

According to some embodiments, the photoelectric conversion region 201p includes germanium or is composed of germanium. According to some embodiments, the photoelectric conversion region 201p includes GeSi or is composed of GeSi. According to some embodiments, the first semiconductor region 230p includes silicon or is composed of silicon. According to some embodiments, the second semiconductor region 240n includes silicon or is composed of silicon.

For example, the first semiconductor region 230p may include amorphous silicon, polycrystalline silicon or single crystalline silicon. The first semiconductor region 230p may be P-type and has a doping concentration not less than 1×10¹⁹ cm⁻³. For example, the second semiconductor region 240n may include crystalline Si and may be N-type. The second semiconductor region 240n has a doping concentration not less 1×10¹⁹ cm⁻³. For example, the photoelectric conversion region 201p may include crystalline Ge having a doping concentration ranging from 1×10¹⁷ cm⁻³ to 1×10¹⁹ cm⁻³. For another example, the photoelectric conversion region 201p may include crystalline Ge layer having a doping concentration not less 1×10¹⁹ cm⁻³.

FIG. 5B is a schematic, cross-sectional diagram showing an exemplary optoelectronic device 20a′ in accordance with still another embodiment of the present application. The conductive contact elements 250, 260 can be at two opposite sides of the substrate 200. In other words, the substrate 200 is between the conductive contact elements 250, 260. According to some embodiments, the substrate 200 is of a conductivity type. In some embodiments, the conductivity type is N-type. In some embodiments, the substrate 200 includes an N-type dopant having a concentration profile including a lowest concentration. In some embodiments, the concentration profile is measured from a top surface of the substrate 200 to a bottom surface of the substrate 200. In some embodiments, the lowest concentration of the N-type dopant is between 1×10¹² cm⁻³ and 5×10¹⁴ cm⁻³ and the thickness of the substrate 200 is not more than 100 μm for a large open-circuit voltage (V_{OC}) and a large short-circuit current (I_{SC}). In some embodiments, the lowest concentration of the N-type dopant is greater than 1×10¹⁵ cm⁻³ or greater than 1×10¹⁶ cm⁻³, and the thickness of the substrate 200 can be greater than 100 μm. In other words, by doping an N-type dopant into the substrate 200 with a lowest concentration greater than 1×10¹⁵ cm⁻³, the thickness of the substrate 200 can be greater than greater than 100 μm, which is beneficial for the manufacturing process of the optoelectronic device 20a′, and the optoelectronic device 20a′ can be with large open-circuit voltage (V_{OC}) and a large short-circuit current (I_{SC}) at the same time. In some embodiments, the lowest concentration of the N-type dopant is between than 1×10¹⁶ cm⁻³ and 1×10¹⁹ cm⁻³. In some embodiments, the substrate 200 is composed of crystalline Si.

According to some embodiments, a material of the first semiconductor region 230p is the same as a material of the photoelectric conversion region 201p. In some embodiments, a material of the second semiconductor region 240n is the same as the material of the photoelectric conversion region 201p. For example, the first semiconductor region 230p, the photoelectric conversion region 201p and the second semiconductor region 240n all include Ge or GeSi. For another example, the first semiconductor region 230p, the photoelectric conversion region 201p and the second semiconductor region 240n are all composed of Ge or Ge Si.

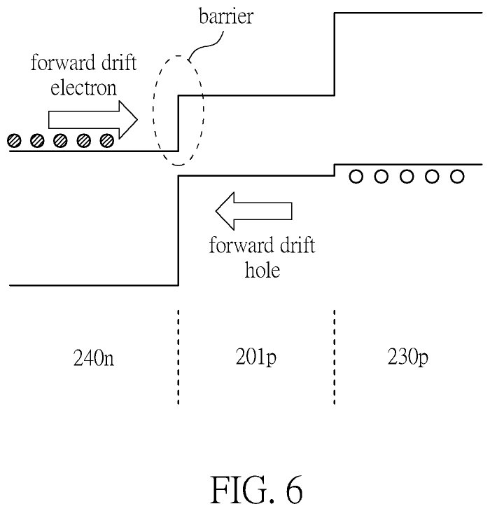

FIG. 6 is a band diagram showing the band structure of the exemplary optoelectronic device 20a of FIG. 5A. It is understood that FIG. 5A is for illustration purposes only. The band diagram does not accurately reflect the barriers caused by band offset or built-in potential. By employing intentionally doped photoelectric conversion region 201p, a barrier can be formed between the photoelectric conversion region 201p and the second semiconductor region 240n. As a result, the forward-biased electrons can be prevented from drifting into the photoelectric conversion region 201p by the barrier between the photoelectric conversion region 201p and the second semiconductor region 240n. In other words, the forward-biased electrons and the holes can be separated by the barrier and be at the two opposite sides of the interface between the second semiconductor region 240n and the photoelectric conversion region 201p. Therefore, the Schocky-Read-Hall recombination can be decreased, thereby increasing V_{OC}. Furthermore, in some embodiments, since the band gap of the second semiconductor region 240n is greater than the band gap of the photoelectric conversion region 201p and/or the band gap of the first semiconductor region 230p is greater than the band gap of the photoelectric conversion region 201p, the barrier between the photoelectric conversion region 201p and the second semiconductor region 240n can be enlarged and thus the forward-biased electrons can be further prevented from drifting into the photoelectric conversion region 201p. Accordingly, V_{OC} can be further increased.

According to some embodiments, the first dopant in the first semiconductor region 230p can be an N-type dopant, the third dopant in the photoelectric conversion region 201p can be an N-type dopant, and the second dopant in the second semiconductor region 240n can be a P-type dopant. By employing intentionally doped photoelectric conversion region 201p, a barrier can be formed between first semiconductor region 230p and the photoelectric conversion region 201p. As a result, the forward-biased holes can be prevented from drifting into the photoelectric conversion region 201p by the barrier between the photoelectric conversion region 201p and the first semiconductor region 230p. In other words, forward-biased holes and the electrons can be separated by the barrier and be at the two opposite sides of the interface between the first semiconductor region 230p and the photoelectric conversion region 201p. Therefore, the Schocky-Read-Hall recombination can be decreased, thereby increasing V_{OC}. Furthermore, in some embodiments, since the band gap of the first semiconductor region 230p is greater than the band gap of the photoelectric conversion region 201p and/or the band gap of the second semiconductor region 240n is greater than the band gap of the photoelectric conversion region 201p, the barrier between the photoelectric conversion region 201p and the first semiconductor region 230p can be enlarged and thus the forward-biased holes can be further prevented from drifting into the photoelectric conversion region 201p. Accordingly, V_{OC} can be further increased.

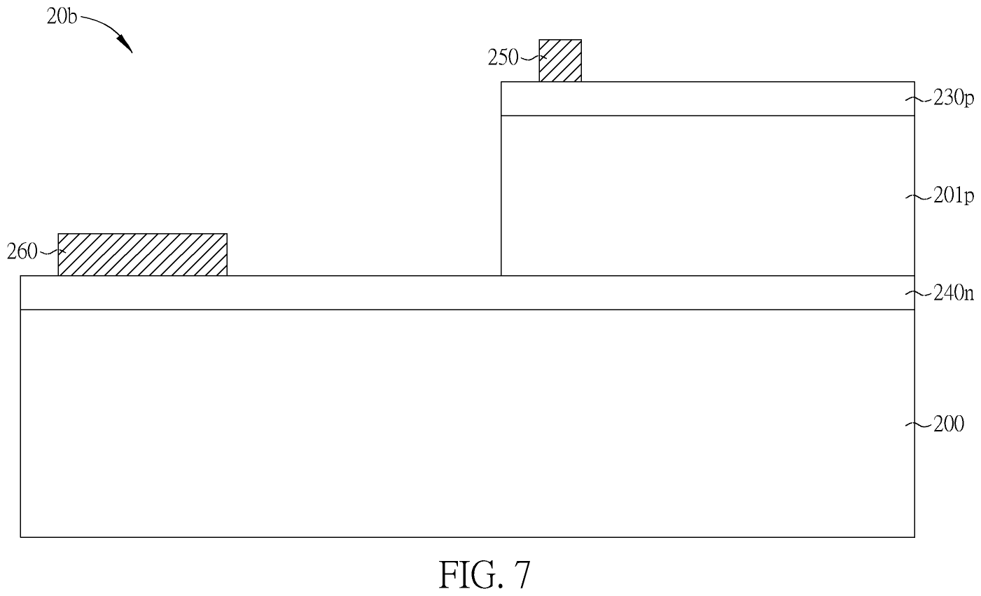

FIG. 7 is a schematic, cross-sectional diagram showing an exemplary optoelectronic device 20b in accordance with still another embodiment of the present application, wherein similar layers, regions or elements are designated by the same numeral numbers. As shown in FIG. 7, for example, the second dopant of the second contact region 240n may diffuse into the photoelectric conversion region 201p or can be intentionally doped into a part of the photoelectric conversion region 201p. In other words, the part of the photoelectric conversion region 201p near the second semiconductor region 240n may include both the second dopant and the third dopant.

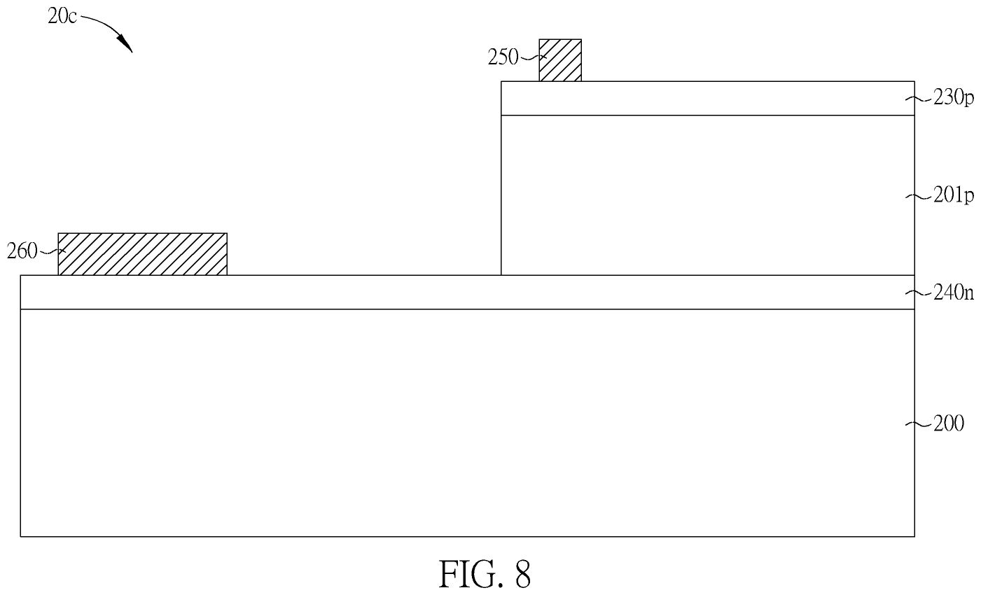

FIG. 8 is a schematic, cross-sectional diagram showing an exemplary optoelectronic device 20c in accordance with still another embodiment of the present application, wherein similar layers, regions or elements are designated by the same numeral numbers. As shown in FIG. 8, for example, the first dopant of the first semiconductor region 230p may diffuse into the photoelectric conversion region 201p.

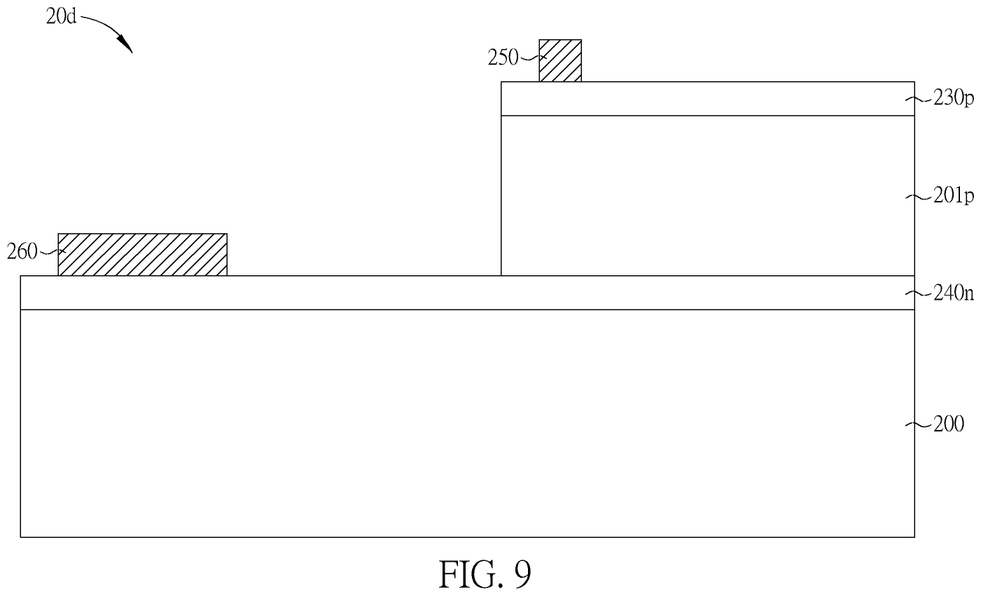

FIG. 9 is a schematic, cross-sectional diagram showing an exemplary optoelectronic device 20d in accordance with still another embodiment of the present application, wherein similar layers, regions or elements are designated by the same numeral numbers. According to one embodiment, a material of the first semiconductor region 230p is the same as a material of the photoelectric conversion region 201p. For example, the first semiconductor region 230p and the photoelectric conversion region 201p both include crystalline Ge. The second semiconductor region 240n is located in the substrate 200 and includes crystalline Si.

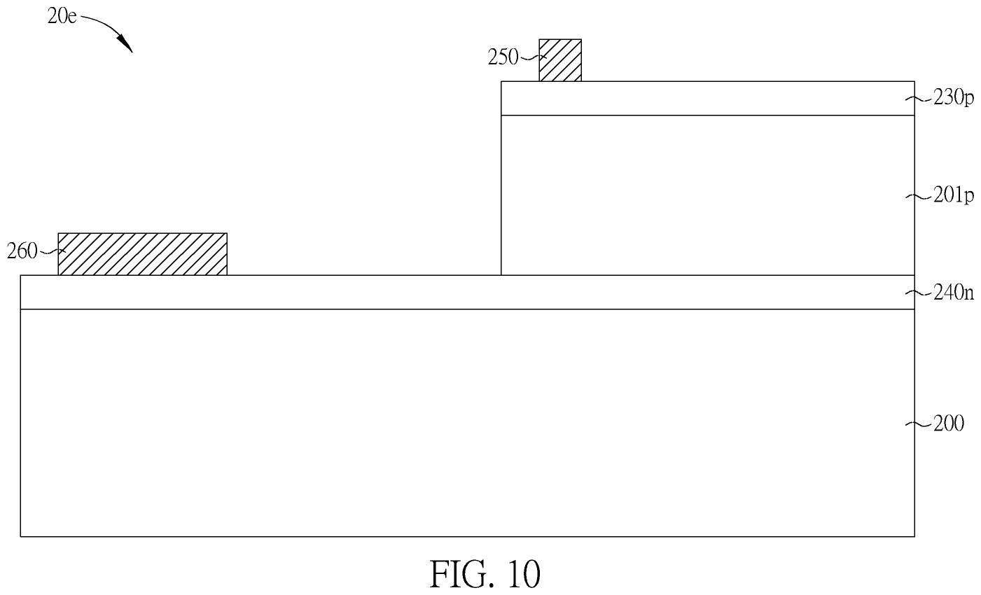

FIG. 10 is a schematic, cross-sectional diagram showing an exemplary optoelectronic device 20e in accordance with still another embodiment of the present application, wherein similar layers, regions or elements are designated by the same numeral numbers. According to one embodiment, a material of the second semiconductor region 240n is the same as the material of the photoelectric conversion region 201p. For example, the first semiconductor region 230p includes amorphous Si, poly crystalline Si, or crystalline Si. The photoelectric conversion region 201p and the second semiconductor region 240n both include crystalline Ge.

According to some embodiments, the optoelectronic device may further include a third semiconductor region between the photoelectric conversion region and the second semiconductor region. In some embodiments, the third semiconductor region is crystalline. In some embodiments, the third semiconductor region is for improving the quality of the photoelectric conversion region formed thereon.

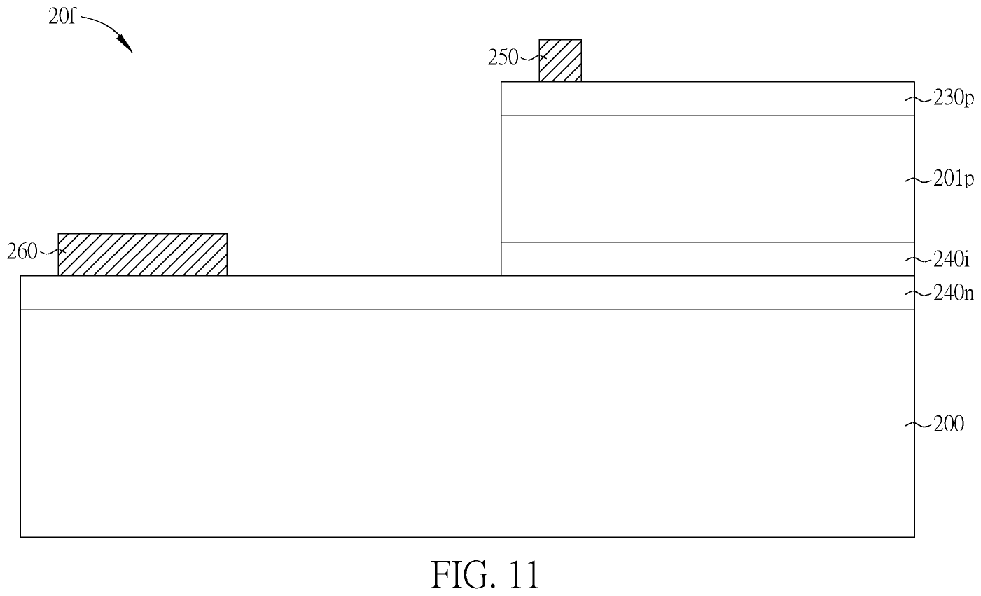

FIG. 11 is a schematic, cross-sectional diagram showing an exemplary optoelectronic device 20f in accordance with still another embodiment of the present application, wherein similar layers, regions or elements are designated by the same numeral numbers. As shown in FIG. 11, the optoelectronic device 20f includes a third semiconductor region 240i between the photoelectric conversion region 201p and the second semiconductor region 240n. In some embodiments, the third semiconductor region 240i is crystalline for improving the quality of the photoelectric conversion region 201p formed thereon. In some embodiments, the third semiconductor region 240i is intrinsic and has a thickness not more than 200 nm for increasing the V_{OC} of the optoelectronic device 20f. In some embodiments, the third semiconductor region 240i may be of a conductivity type the same as the second conductivity type of the second semiconductor region 240n. In some embodiments, the third semiconductor region 240i may include crystalline Si. In some embodiments, the material of the third semiconductor region 240i is the same as the material of the substrate 200. In some embodiments, a substantially invisible interface may be between the third semiconductor region 240i and the substrate 200.

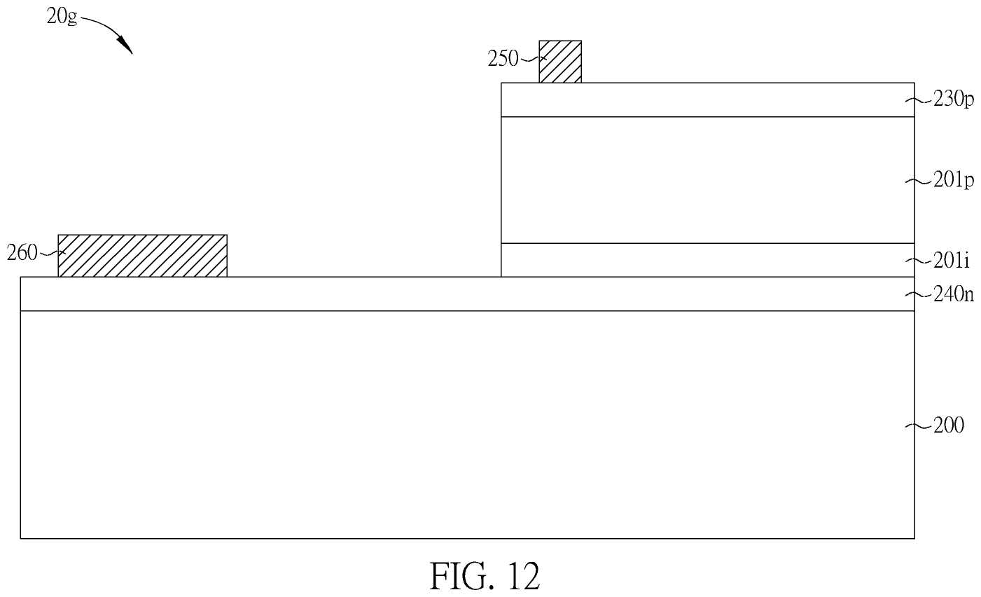

FIG. 12 is a schematic, cross-sectional diagram showing an exemplary optoelectronic device 20g in accordance with still another embodiment of the present application, wherein similar layers, regions or elements are designated by the same numeral numbers. As shown in FIG. 12, the optoelectronic device 20g includes a fourth semiconductor region 201i between the photoelectric conversion region 201p and the second semiconductor region 240n. The fourth semiconductor region 201i is intrinsic. The fourth semiconductor region 201i may be an undoped or lightly doped region, such as having a peak concentration not more than 1×10¹⁶ cm⁻³. According to one embodiment, the fourth semiconductor region 201i may include crystalline Ge, which can ease the epitaxy growth of the photoelectric conversion region 201p. According to some embodiments, an optoelectronic device can also include both a third semiconductor region 240i (as set forth in FIG. 11) and a fourth semiconductor region 201i, wherein the third semiconductor region 240i is between the second semiconductor region 240n and the photoelectric conversion region 201p, and the fourth semiconductor region 201i is between the third semiconductor region 240i and the photoelectric conversion region 201p.

According to some embodiments, the third dopant of the photoelectric conversion region may have a concentration, wherein the concentration is graded along a direction from the first semiconductor region with the conductivity type the same as the conductivity type of the photoelectric conversion region to the second semiconductor region with the conductivity type the different from the conductivity type of the photoelectric conversion region. In some embodiments, the concentration is gradually decreased along a direction from the first semiconductor region to the second semiconductor region. According to some embodiments, the concentration is gradually decreased along a direction from the P-type first semiconductor region to the N-type second semiconductor region when the photoelectric conversion region is P-type.

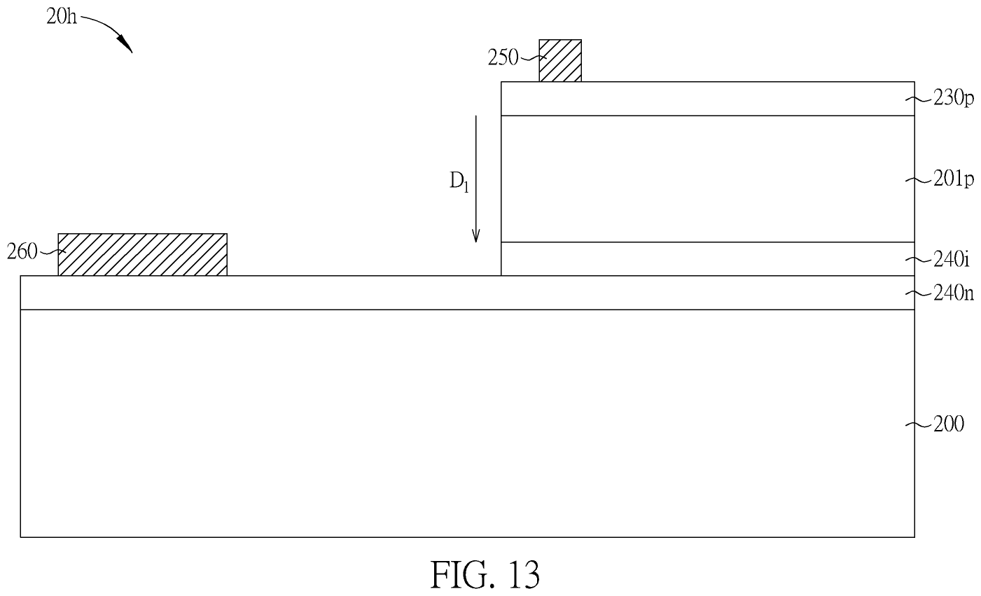

FIG. 13 is a schematic, cross-sectional diagram showing an exemplary optoelectronic device 20h in accordance with still another embodiment of the present application, wherein similar layers, regions or elements are designated by the same numeral numbers. As shown in FIG. 13, the photoelectric conversion region 201p includes the third dopant (e.g., P type dopant) having a concentration, wherein the concentration is graded along a direction D₁ from the first semiconductor region 230p to the second semiconductor region 240n. In some embodiments, the concentration is gradually decreased along the direction D₁ from the first semiconductor region 230p to the second semiconductor region 240n.

According to some embodiments, an optoelectronic device may include a photoelectric conversion region including a first side and a second side opposite to the first side; a first semiconductor region of a first conductivity type; and a second semiconductor region of a second conductivity type different from the first conductivity type. The first semiconductor region and the second semiconductor region are both over the first side of photoelectric conversion region. The photoelectric conversion region is of a third conductivity type the same as the first conductivity type.

In some embodiments, the optoelectronic device further includes a third semiconductor region separating the photoelectric conversion region and the second semiconductor region. In some embodiments, the third semiconductor region is similar with that as described in FIG. 11.

In some embodiments, the first semiconductor region is in direct contact with the photoelectric conversion region. In some embodiments, the first semiconductor region serves as a semiconductor contact region. In some embodiments, the second semiconductor region is in direct contact with the photoelectric conversion region. In some embodiments, the second semiconductor region serves as a semiconductor contact region.

In some embodiments, a material of the first semiconductor region is different from a material of the photoelectric conversion region. In some embodiments, the material of the first semiconductor region is the same as a material of the second semiconductor region. In some embodiments, a direction from the first semiconductor region to the second semiconductor region is substantially perpendicular to a direction from the first side and the second side of the photoelectric conversion region. In some embodiments, the first semiconductor region is physically separated from the second semiconductor region.

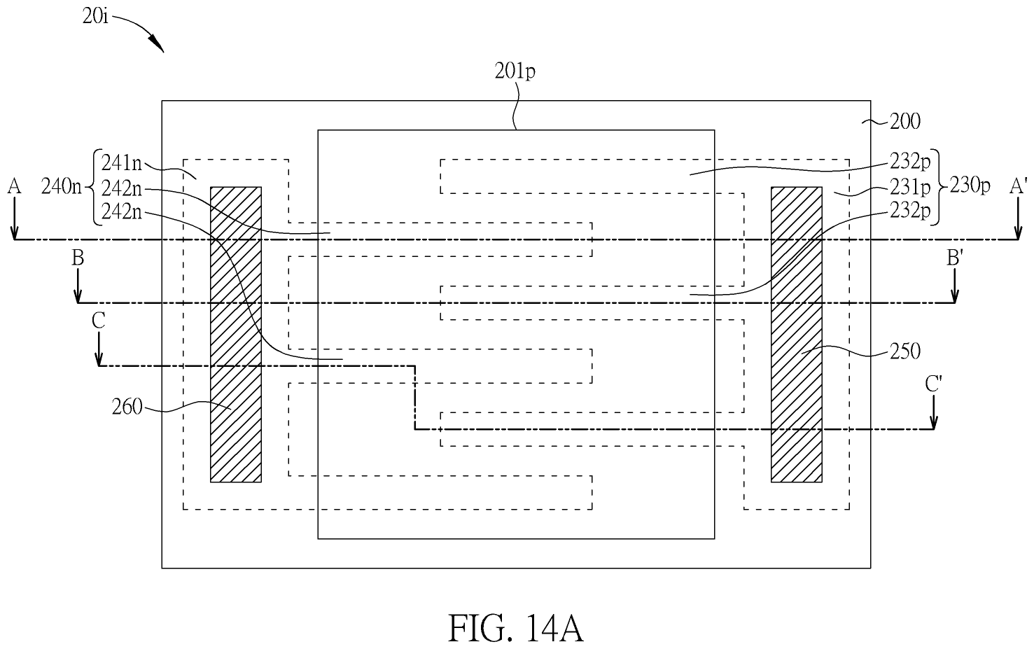

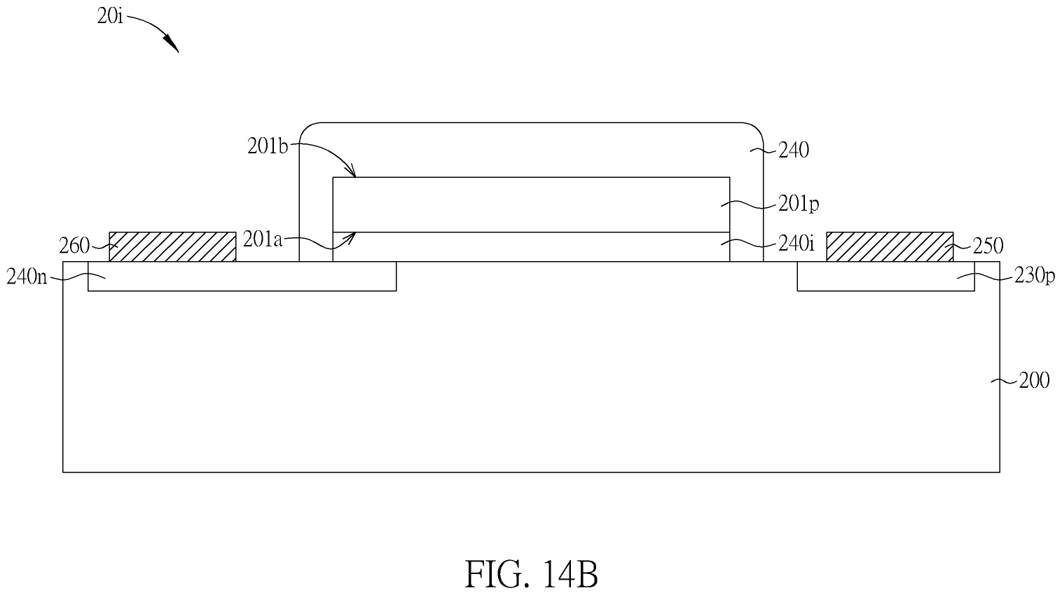

FIG. 14A is a schematic, top-view diagram showing an exemplary optoelectronic device 20i in accordance with still another embodiment of the present application. FIG. 14B is a schematic, cross-sectional diagram along an A-A′ line in FIG. 14A, wherein similar layers, regions or elements are designated by the same numeral numbers. The photoelectric conversion region 201p includes a first side 201a and a second side 201b opposite to the first side 201a. A first semiconductor region 230p of a first conductivity type (e.g., P type) is disposed in the substrate 200. In some embodiments, the first semiconductor region 230p includes crystalline Si. A second semiconductor region 240n of a second conductivity type (e.g., N type) different from the first conductivity type is also disposed in the substrate 200. In some embodiments, the second semiconductor region 240n includes crystalline Si. The first semiconductor region 230p and the second semiconductor region 240n are both disposed on the first side 201a of photoelectric conversion region 201p. The photoelectric conversion region 201p is of a third conductivity type the same as the first conductivity type.

In some embodiments, the optoelectronic device 20i further includes a passivation layer 240 covering a top surface of the photoelectric conversion region 201p. In some embodiments, the passivation layer 240 covers the top surface of the photoelectric conversion region 201p and covers all the side walls of the photoelectric conversion region 201p. In some embodiment, a material of the passivation layer 240 is different from a material of the photoelectric conversion region 201p. In some embodiments, the passivation layer 240 reduces surface defects of the photoelectric conversion region 201p. In some embodiments, the passivation layer 240 protects the surface of the photoelectric conversion region 201p from contamination or damages from the environment. In some embodiments, the passivation layer 240 includes amorphous silicon.

As shown in FIG. 14A and FIG. 14B, the first semiconductor region 230p and the second semiconductor region 240n are formed at a side of the substrate near the photoelectric conversion region 201p. The first semiconductor region 230p includes a first main portion 231p. The second semiconductor region 240n includes a second main portion 241n. The first main portion 231p and the second main portion 241n are disposed at two opposite sides of the photoelectric conversion region 201p and are not covered by the photoelectric conversion region 201p. The first semiconductor region 230p further includes a first extension portion 232p extending from the first main portion 231p toward the second main portion 241n. The second semiconductor region 240n further includes a second extension portion 242n extending from the second main portion 241n toward the first main portion 231p. The first extension portion 232p and the second extension portion 242n are covered by the photoelectric conversion region 201p. The conductive contact element 250 is disposed on the first main portion 231p. The conductive contact element 260 is disposed on the second main portion 241n. In some embodiments, the first semiconductor region 230p includes multiple first extension portions 232p each extending from the first main portion 231p toward the second main portion 241n and separated from each other. In some embodiments, the second semiconductor region 240n further includes multiple second extension portions 242n each extending from the second main portion 241n toward the first main portion 231p and separated from each other. The multiple first extension portions 232p and the multiple second extension portions 242n are arranged alternately and are covered by the photoelectric conversion region 201p.

According to one embodiment, the first semiconductor region 230p is physically separated from the second semiconductor region 240n. The optoelectronic device 20i further includes a third semiconductor region 240i separating the photoelectric conversion region 201p and the first semiconductor region 230p and separating the photoelectric conversion region 201p and the second semiconductor region 240n. In other words, the third semiconductor region 240i is between the photoelectric conversion region 201p and the first semiconductor region 230p. The third semiconductor region 240i is between the photoelectric conversion region 201p and the second semiconductor region 240n. In some embodiments, the third semiconductor region 240i is intrinsic. In some embodiments, the conductive contact element 250 such as electrode is in direct contact with the first semiconductor region 230p. In other words, the first semiconductor region 230p serves as a semiconductor contact region. In some embodiments, the conductive contact element 260 such as electrode is in direct contact with the second semiconductor region 240n. In other words, the second semiconductor region 240n serves as a semiconductor contact region.

A material of the first semiconductor region 230p is different from a material of the photoelectric conversion region 201p. In some embodiments, the material of the first semiconductor region 230p is the same as a material of the second semiconductor region 240n. A direction from the first semiconductor region 230p to the second semiconductor region 240n is substantially perpendicular to a direction from the first side 201a to the second side 201b of the photoelectric conversion region 201p.

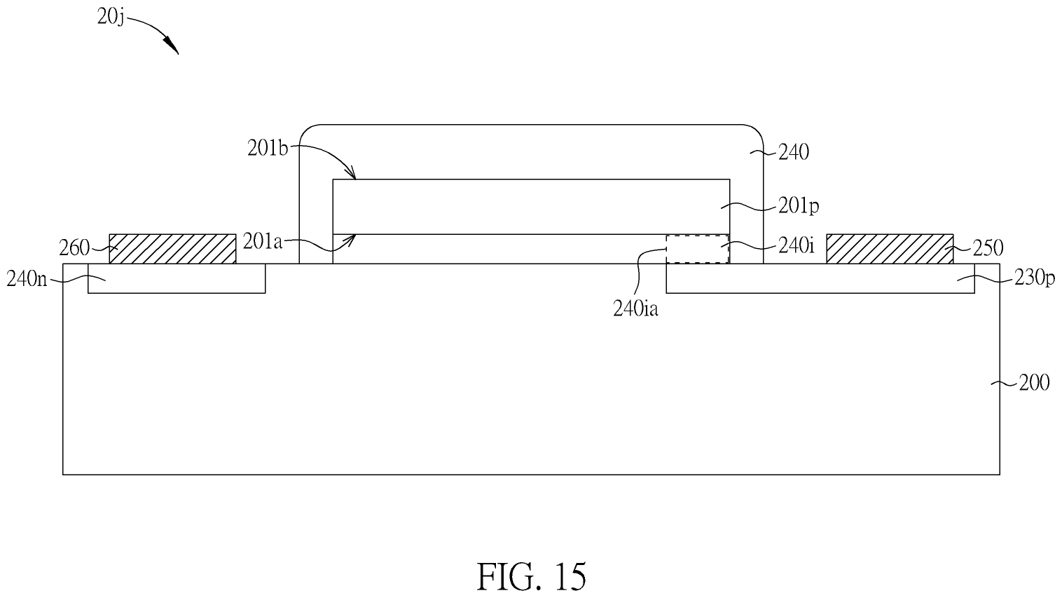

FIG. 15 is a schematic, cross-sectional diagram showing an exemplary optoelectronic device 20j in accordance with still another embodiment of the present application, wherein the optoelectronic device 20j has a top view similar to the top view in FIG. 14A and the cross-sectional diagram is along an B-B′ line in FIG. 14A, and wherein similar layers, regions or elements are designated by the same numeral numbers. As shown in FIG. 15, the optoelectronic device 20j includes a photoelectric conversion region 201p including a first side 201a and a second side 201b opposite to the first side 201a. A first semiconductor region 230p of a first conductivity type (e.g., P type) is disposed in the substrate 200. A second semiconductor region 240n of a second conductivity type (e.g., N type) different from the first conductivity type is disposed in the substrate 200 and separated from the first semiconductor region 230p. The first semiconductor region 230p and the second semiconductor region 240n are both disposed on the first side 201a of photoelectric conversion region 201p. The photoelectric conversion region 201p is of a third conductivity type the same as the first conductivity type.

According to one embodiment, the optoelectronic device 20j further includes a third semiconductor region 240i separating the photoelectric conversion region 201p from the second semiconductor region 240n and separating the first semiconductor region 230p from the photoelectric conversion region 201p. In other words, the third semiconductor region 240i is between the photoelectric conversion region 201p and the first semiconductor region 230p. The third semiconductor region 240i is between the photoelectric conversion region 201p and the second semiconductor region 240n. In some embodiments, the third semiconductor region 240i is intrinsic. In some embodiments, the first dopant of the first semiconductor region 230p may diffuse into the third semiconductor region 240i during the manufacturing process of the optoelectronic device, such as the step of forming the third semiconductor region 240i. As a result, a part 240ia of the third semiconductor region 240i between the first semiconductor region 230p and the photoelectric conversion region 201p includes the first dopant.

The conductive contact element 250 such as electrode is in direct contact with the first semiconductor region 230p. In other words, the first semiconductor region 230p serves as a semiconductor contact region. The conductive contact element 260 such as electrode is in direct contact with the second semiconductor region 240n. In other words, the second semiconductor region 240n serves as a semiconductor contact region.

According to one embodiment, the first semiconductor region 230p is physically separated from the second semiconductor region 240n. According to one embodiment, the optoelectronic device 20j further includes a fourth semiconductor region between the third semiconductor region 240i and the photoelectric conversion region 201p. The fourth semiconductor region can be similar to the fourth semiconductor region 201i as described in FIG. 12.

A material of the first semiconductor region 230p is different from a material of the photoelectric conversion region 201p. In some embodiments, the material of the first semiconductor region 230p is the same as a material of the second semiconductor region 240n. A direction from the first semiconductor region 230p to the second semiconductor region 240n is substantially perpendicular to a direction from the first side 201a to the second side 201b of the photoelectric conversion region 201p.

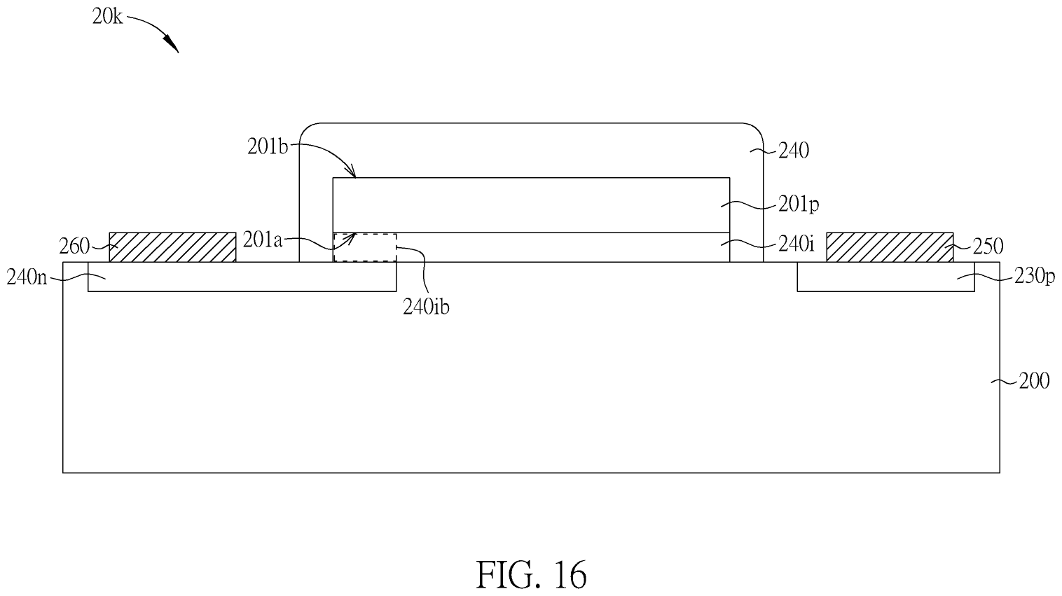

FIG. 16 is a schematic, cross-sectional diagram showing an exemplary optoelectronic device 20k in accordance with still another embodiment of the present application, wherein the optoelectronic device 20k has a top view similar to the top view in FIG. 14A and the cross-sectional diagram is along an A-A′ line in FIG. 14A, and wherein similar layers, regions or elements are designated by the same numeral numbers. As shown in FIG. 16, the optoelectronic device 20k includes a photoelectric conversion region 201p including a first side 201a and a second side 201b opposite to the first side 201a. A first semiconductor region 230p of a first conductivity type (e.g., P type) is disposed in the substrate 200. A second semiconductor region 240n of a second conductivity type (e.g., N type) different from the first conductivity type is disposed in the substrate 200 and physically separated from the first semiconductor region 230p. The first semiconductor region 230p and the second semiconductor region 240n are both disposed on the first side 201a of photoelectric conversion region 201p. The photoelectric conversion region 201p is of a third conductivity type the same as the first conductivity type.

According to one embodiment, the optoelectronic device 20k further includes a third semiconductor region 240i separating the photoelectric conversion region 201p from the first semiconductor region 230p and separating the photoelectric conversion region 201p from the second semiconductor region 240n. In some embodiments, the third semiconductor region 240i is intrinsic.

In some embodiments, the second dopant of the second semiconductor region 240n may diffuse into the third semiconductor region 240i during the manufacturing process of the optoelectronic device, such as the step of forming the third semiconductor region 240i. As a result, a part 240ib of the third semiconductor region 240i between the second semiconductor region 240n and the photoelectric conversion region 201p includes the second dopant.

The conductive contact element 250 such as electrode is in direct contact with the first semiconductor region 230p. In other words, the first semiconductor region 230p serves as a semiconductor contact region. The conductive contact element 260 such as electrode is in direct contact with the second semiconductor region 240n. In other words, the second semiconductor region 240n serves as a semiconductor contact region.

According to one embodiment, the first semiconductor region 230p is physically separated from the second semiconductor region 240n. According to one embodiment, the optoelectronic device 20k further includes a fourth semiconductor region between the third semiconductor region 240i and the photoelectric conversion region 201p. The fourth semiconductor region can be similar to the fourth semiconductor region 201i as described in FIG. 12.

A material of the first semiconductor region 230p is different from a material of the photoelectric conversion region 201p. In some embodiments, the material of the first semiconductor region 230p is the same as a material of the second semiconductor region 240n. A direction from the first semiconductor region 230p to the second semiconductor region 240n is substantially perpendicular to a direction from the first side 201a to the second side 201b of the photoelectric conversion region 201p.

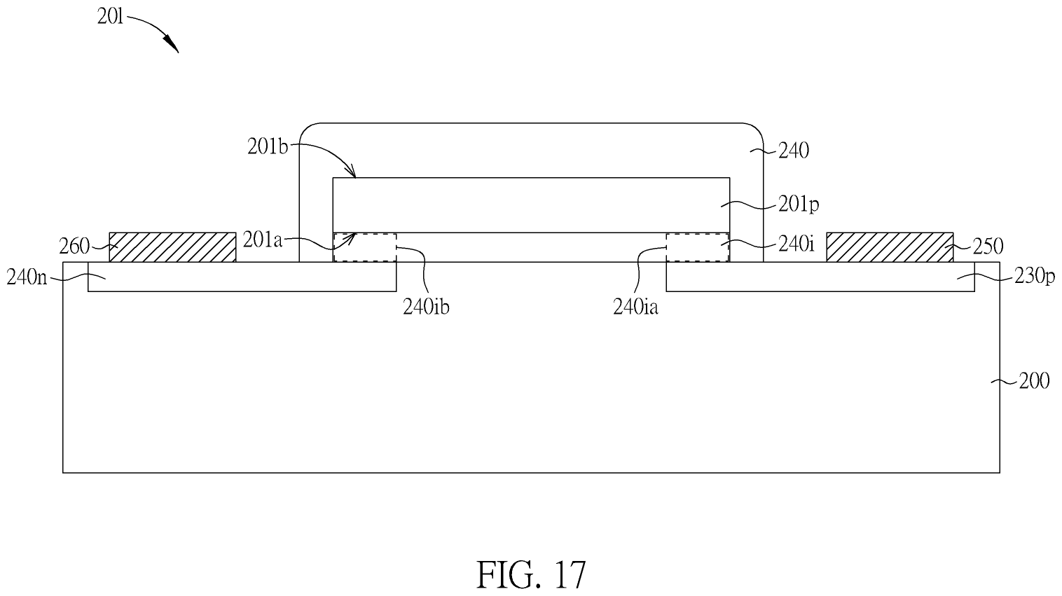

FIG. 17 is a schematic, cross-sectional diagram showing an exemplary optoelectronic device 201 in accordance with still another embodiment of the present application, wherein the optoelectronic device 201 has a top view similar to the top view in FIG. 14A and the cross-sectional diagram is along an C-C′ line in FIG. 14A, and wherein similar layers, regions or elements are designated by the same numeral numbers. As shown in FIG. 17, the optoelectronic device 201 includes a photoelectric conversion region 201p including a first side 201a and a second side 201b opposite to the first side 201a. A first semiconductor region 230p of a first conductivity type (e.g., P type) is disposed in the substrate 200. A second semiconductor region 240n of a second conductivity type (e.g., N type) different from the first conductivity type is disposed in the substrate 200 and physically separated from the first semiconductor region 230p. The first semiconductor region 230p and the second semiconductor region 240n are both disposed on the first side 201a of photoelectric conversion region 201p. The photoelectric conversion region 201p is of a third conductivity type the same as the first conductivity type.

According to one embodiment, the first semiconductor region 230p is physically separated from the second semiconductor region 240n. The optoelectronic device 201 further includes a third semiconductor region 240i separating the first semiconductor region 230p from the second semiconductor region 240n. In some embodiments, the third semiconductor region 240i is intrinsic.

In some embodiments, the first dopant of the first semiconductor region 230p may diffuse into the third semiconductor region 240i during the manufacturing process of the optoelectronic device, such as the step of forming the third semiconductor region 240i. As a result, a part 240ia of the third semiconductor region 240i between the first semiconductor region 230p and the photoelectric conversion region 201p includes the first dopant. In some embodiments, the second dopant of the second semiconductor region 240n may diffuse into the third semiconductor region 240i during the manufacturing process of the optoelectronic device, such as the step of forming the third semiconductor region 240i. As a result, a part 240ib of the third semiconductor region 240i between the second semiconductor region 240n and the photoelectric conversion region 201p includes the second dopant. In other words, the third semiconductor region 240i may include both the first dopant and the second dopant.

The conductive contact element 250 such as electrode is in direct contact with the first semiconductor region 230p. In other words, the first semiconductor region 230p serves as a semiconductor contact region. The conductive contact element 260 such as electrode is in direct contact with the second semiconductor region 240n. In other words, the second semiconductor region 240n serves as a semiconductor contact region.

A material of the first semiconductor region 230p is different from a material of the photoelectric conversion region 201p. In some embodiments, the material of the first semiconductor region 230p is the same as a material of the second semiconductor region 240n. A direction from the first semiconductor region 230p to the second semiconductor region 240n is substantially perpendicular to a direction from the first side 201a to the second side 201b of the photoelectric conversion region 201p.

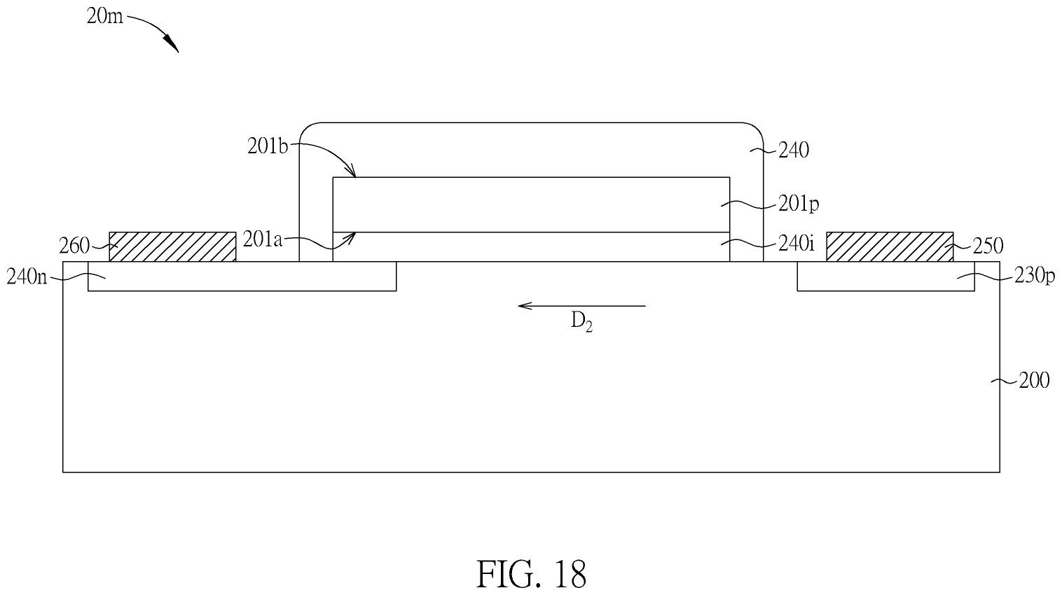

FIG. 18 is a schematic, cross-sectional diagram showing an exemplary optoelectronic device 20m in accordance with still another embodiment of the present application, wherein the optoelectronic device 20m has a top view similar to the top view in FIG. 14A and the cross-sectional diagram is along an A-A′ line in FIG. 14A, and wherein similar layers, regions or elements are designated by the same numeral numbers. As shown in FIG. 18, the optoelectronic device 20m includes a photoelectric conversion region 201p including a first side 201a and a second side 201b opposite to the first side 201a. A first semiconductor region 230p of a first conductivity type (e.g., P type) is disposed in the substrate 200. A second semiconductor region 240n of a second conductivity type (e.g., N type) different from the first conductivity type is disposed in the substrate 200 and physically separated from the first semiconductor region 230p. The first semiconductor region 230p and the second semiconductor region 240n are both disposed on the first side 201a of photoelectric conversion region 201p. The photoelectric conversion region 201p is of a third conductivity type the same as the first conductivity type.

According to one embodiment, the first semiconductor region 230p is physically separated from the second semiconductor region 240n. The optoelectronic device 20m further includes a third semiconductor region 240i separating the photoelectric conversion region 201p, the first semiconductor region 230p and the second semiconductor region 240n. In some embodiments, the third semiconductor region 240i is intrinsic. The conductive contact element 250 such as electrode is in direct contact with the first semiconductor region 230p. In other words, the first semiconductor region 230p serves as a semiconductor contact region. The conductive contact element 260 such as electrode is in direct contact with the second semiconductor region 240n. In other words, the second semiconductor region 240n serves as a semiconductor contact region.

A material of the first semiconductor region 230p is different from a material of the photoelectric conversion region 201p. In some embodiments, the material of the first semiconductor region 230p is the same as a material of the second semiconductor region 240n. A direction from the first semiconductor region 230p to the second semiconductor region 240n is substantially perpendicular to a direction from the first side 201a to the second side 201b of the photoelectric conversion region 201p.

According to one embodiment, the photoelectric conversion region 201p includes a dopant (e.g., P type dopant) having a concentration, wherein the concentration is graded along a direction D₂ from the first semiconductor region 230p to the second semiconductor region 240n. In some embodiments, the concentration is gradually decreased along the direction D₂ from the first semiconductor region 230p with the conductivity type the same as the conductivity type of the photoelectric conversion region 201p to the second semiconductor region 240n with the conductivity type the different from the conductivity type of the photoelectric conversion region 201p to facilitate electron transport. According to some embodiments, the concentration is gradually decreased along a direction from the p-type first semiconductor region 230p to the N-type second semiconductor region 240n when the photoelectric conversion region 201p is P-type.

In some embodiments, the structure of the optoelectronic device or the photovoltaic cell may be a combination of the previously shown embodiments. It is to be understood that the conductivity types of the layers can be opposite. For example, in some embodiment, the P⁺ region can be N⁺ region, the N⁺⁺ region can be P⁺⁺ region, and the P⁺⁺ region can be N⁺⁺ region.

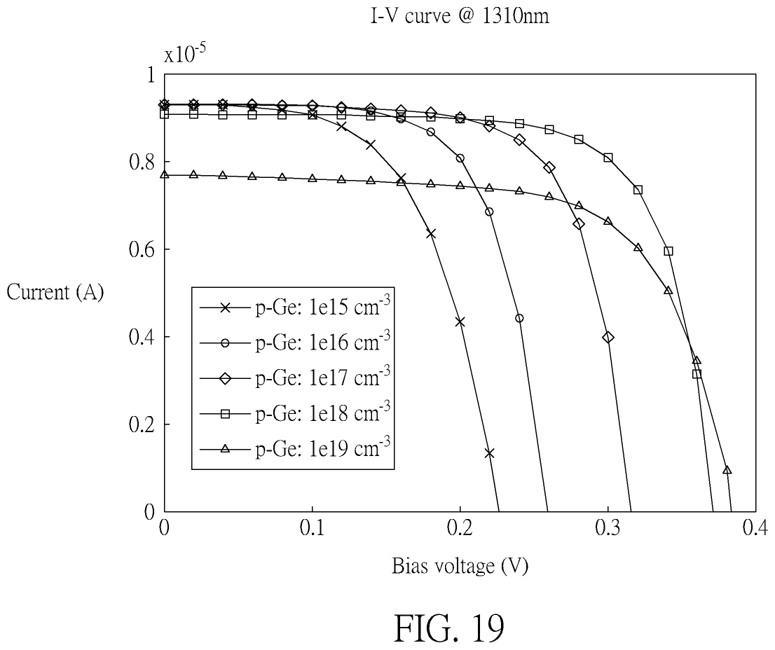

FIG. 19 demonstrates simulation results of I-V curves of optoelectronic devices in FIG. 11 with different peak concentrations of the dopant in the photoelectric conversion region 201p, wherein the photoelectric conversion region 201p is composed of germanium. In FIG. 19, the optoelectronic devices with a photoelectric conversion region 201p having a peak concentration between 1×10¹⁷ cm⁻³ and 1×10¹⁹ cm⁻³ have relatively better Voc.

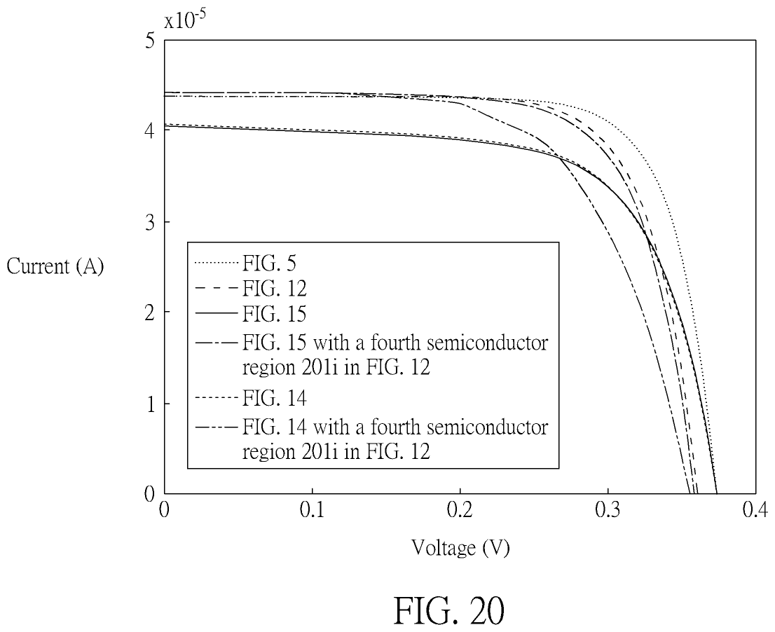

Please refer to FIG. 20, which shows the I-V curves of different optoelectronic devices with the photoelectric conversion region 201p composed of germanium and having a peak concentration about 1×10¹⁸ cm⁻³. As shown in FIG. 20, each of the optoelectronic devices in accordance with the present application has good Voc.

According to one embodiment, the optoelectronic device may be a photodetector.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An optoelectronic device, comprising:
a first semiconductor region of a first conductivity type;
a second semiconductor region of a second conductivity type different from the first conductivity type; and
a photoelectric conversion region between the first semiconductor region and the second semiconductor region, wherein the photoelectric conversion region is of a third conductivity type the same as the first conductivity type.

2. The optoelectronic device according to claim 1, wherein the first semiconductor region comprises a first dopant having a first peak concentration, the second semiconductor region comprises a second dopant having a second peak concentration, the photoelectric conversion region comprises a third dopant having a third peak concentration, and wherein the third peak concentration is not less than 1×10¹⁷ cm⁻³.

3. The optoelectronic device according to claim 2, wherein the first peak concentration is higher than the third peak concentration.

4. The optoelectronic device according to claim 1, wherein a material of the first semiconductor region is the same as a material of the photoelectric conversion region, and wherein a material of the second semiconductor region is the same as the material of the photoelectric conversion region.

5. The optoelectronic device according to claim 1, wherein a material of the first semiconductor region is different from a material of the photoelectric conversion region, and wherein a material of the second semiconductor region is different from the material of the photoelectric conversion region.

6. The optoelectronic device according to claim 1, wherein the photoelectric conversion region comprises germanium.

7. The optoelectronic device according to claim 1, wherein the first semiconductor region comprises a band gap greater than a band gap of the photoelectric conversion layer.

8. The optoelectronic device according to claim 1, wherein the second semiconductor region comprises silicon and/or the first semiconductor region comprises silicon.

9. The optoelectronic device according to claim 1, wherein the photoelectric conversion region comprises a dopant having a concentration, wherein the concentration is graded along a direction from the first semiconductor region to the second semiconductor region.

10. The optoelectronic device according to claim 9, wherein the concentration is gradually decreased along a direction from the first semiconductor region to the second semiconductor region.

11. The optoelectronic device according to claim 1, wherein the first conductivity type is P type and the second conductivity type is N type.

12. The optoelectronic device according to claim 1, further comprising a third semiconductor region between the photoelectric conversion region and the second semiconductor region.

13. The optoelectronic device according to claim 2, wherein the photoelectric conversion region comprises both the second dopant and the third dopant.

14. An optoelectronic device, comprising:
a photoelectric conversion region comprising a first side and a second side opposite to the first side;
a first semiconductor region of a first conductivity type; and
a second semiconductor region of a second conductivity type different from the first conductivity type;
wherein the first semiconductor region and the second semiconductor region are both over the first side of photoelectric conversion region, and the photoelectric conversion region is of a third conductivity type the same as the first conductivity type.

15. The optoelectronic device according to claim 14, wherein the photoelectric conversion region has a peak concentration not less than 1×10¹⁷ cm⁻³.

16. The optoelectronic device according to claim 14, further comprising a passivation layer covering the photoelectric conversion region.

17. The optoelectronic device according to claim 14, wherein a material of the first semiconductor region is different from a material of the photoelectric conversion region, and wherein the material of the first semiconductor region is the same as a material of the second semiconductor region.

18. The optoelectronic device according to claim 14, wherein a direction from the first semiconductor region to the second semiconductor region is substantially perpendicular to a direction from the first side to the second side of the photoelectric conversion region.

19. The optoelectronic device according to claim 14, wherein the first semiconductor region is physically separated from the second semiconductor region.

20. The optoelectronic device according to claim 14, further comprising a third semiconductor region between the photoelectric conversion region and the first semiconductor region.
